(19) United States
(12) Patent Application Publication
(10) Pub. No.: US 2010/0276736 A1
(43) Pub. Date: Nov. 4, 2010

(54) CMOS IMAGE SENSOR ON STACKED SEMICONDUCTOR-ON-INSULATOR SUBSTRATE AND PROCESS FOR MAKING SAME

(76) Inventors: Mark Frederick Bocko, Caledonia, NY (US); Zeljko Ignjatovic, Rochester, NY (US); Carlo Anthony Kosik Williams, Painted Post, NY (US); Donnell Thaddeus Walton, Painted Post, NY (US); ChuanChe Wang, Horseheads, NY (US); James Matthew Zavislan, Pittsford, NY (US)

Correspondence Address: CORNING INCORPORATED, SP-TI-3-1, CORNING, NY, 14831, US

(21) Appl. No.: 12/771,544

(22) Filed: Apr. 30, 2010

Related U.S. Application Data
(60) Provisional application No. 61/174,118, filed on Apr. 30, 2009.

(51) Int. Cl. H01L 27/146; H01L 31/18

(52) U.S. Cl. 257/291; 438/73; 257/E27.134

(57) ABSTRACT

Methods and apparatus for producing a CMOS image sensor result in a plurality of photo sensitive layers, each layer including: a glass or glass ceramic substrate having first and second spaced-apart surfaces; a semiconductor layer disposed on the first surface of the glass or glass ceramic substrate; and a plurality of pixel structures formed in the semiconductor layer, each pixel structure including a plurality of semiconductor islands, at least one island operating as a color sensitive photo-detector sensitive to a respective range of light wavelengths, wherein the plurality of photo sensitive layers are stacked one on the other, such that incident light enters the CMOS image sensor through the first spaced-apart surface of the glass or glass ceramic substrate of one of the plurality of photo sensitive layers, and subsequently passes into further photo sensitive layers if one or more wavelengths of the incident light are sufficiently long.

### PRIORITY

This application claims the benefit of U.S. Provisional Patent Application No. 61/174,118, filed Apr. 30, 2009, titled “CMOS IMAGE SENSOR ON STACKED SEMICONDUCTOR-ON-INSULATOR SUBSTRATE AND PROCESS FOR MAKING SAME”, the entire disclosure of which is hereby incorporated by reference.

### BACKGROUND

One or more embodiments herein relate to image sensors formed of CMOS transistors and fabricated on a semiconductor-on-insulator (SOI) structures, and methods of manufacturing same.

CMOS image sensors are used for a variety of camera products such as digital still cameras, cell phone cameras, automotive cameras and security cameras. CMOS technology is attractive for use in such applications because CMOS transistors exhibit low power consumption characteristics and may be fabricated at relatively low manufacturing costs. The achievable pixel size of CMOS image sensors has been steadily decreasing as the technology matures and, thus, higher resolution images are available from increasingly smaller camera product packages. As the pixel size decreases, however, there is a corresponding degradation in the photodiode sensitivity of each pixel, lowering of optical collection efficiency, increased optical crosstalk, and increased electrical crosstalk within and between pixels.

As to the optical crosstalk problem, the optical components of a conventional CMOS imaging system include a main lens structure (including a color filter array, CFA) and a pixel-level micro-lens array. These structures present a major limitation for further CMOS image sensor scaling. The micro-lens and color filter array (CFA) present significant limitations on pixel size shrinking. As the pixel size decreases, pixel sensitivity is reduced as well as the ratio of signal to photonic noise. Additionally, low f-number (f/#) lens structures are required to increase the number of incident photons on the detection array. Unfortunately, as the f/# goes down, the lens cost goes up by the inverse-square of the f/# and undesirable optical aberrations increase. Such aberrations reduce the micro-lens efficiency, and require corrective measures, such as advanced micro-lens processing.

As to the electrical crosstalk problem, as the pixel size continues to scale down, there is an increased probability that the charge photo-generated deep within the bulk silicon will be collected by neighboring pixels. As a result, a point spread function of the imager widens and the modulation transfer function (MTF) degrades, which leads to compromised image quality.

The above problems are typically associated with a conventional CMOS image sensor that has been fabricated in bulk silicon. There has been some effort in the prior art to develop CMOS image sensors having various pixel structures to address one or more of these problems. Such pixel structures include the use of silicon on a transparent insulator substrate to allow for reduced electrical crosstalk and improved optical collection efficiency. In another case, an improvement in resolution attributable to the color separation function was achieved using vertically stacked wavelength sensor layers in a bulk silicon wafer.

The prior art attempts to address the problems of lower photodiode sensitivity, lower optical collection efficiency, increased optical and electrical crosstalk, and poor color separation in CMOS image sensors, while admirable, have not addressed enough of the problems in one, integrated solution. Thus, there are needs in the art for new methods and apparatus for fabricating CMOS image sensors.

### SUMMARY

In accordance with one or more embodiments herein, methods and apparatus result in novel CMOS pixel structures fabricated on SOI substrates, such as silicon on glass ceramic (SiOGC), including a novel color separation technique and/or aberration correction, which may collectively address the issues of photodiode sensitivity, optical collection efficiency, optical crosstalk, electrical crosstalk, and color separation.

Methods and apparatus provide for a CMOS image sensor, comprising a plurality of photo sensitive layers, each layer including: a glass or glass ceramic substrate having first and second spaced-apart surfaces; a semiconductor layer disposed on the first surface of the glass or glass ceramic substrate; and a plurality of pixel structures formed in the semiconductor layer, each pixel structure including a plurality of semiconductor islands, at least one island operating as a color sensitive photo-detector sensitive to a respective range of light wavelengths. The plurality of photo sensitive layers are stacked one on the other, such that incident light enters the CMOS image sensor through the first spaced-apart surface of the glass or glass ceramic substrate of one of the plurality of photo sensitive layers, and subsequently passes into further photo sensitive layers if one or more wavelengths of the incident light are sufficiently long.

The thicknesses of at least two semiconductor islands of respective color sensitive photo-detectors on differing photo sensitive layers may differ as a function of the respective range of light wavelengths to which they are sensitive. For example, a first semiconductor island operating as a photo-detector of a first of the photo sensitive layers may be of a first thickness for detecting blue light. Additionally or alternatively, a second semiconductor island operating as a photo-detector of a second of the photo sensitive layers may be of a second thickness for detecting green light. Also additionally or alternatively, a third semiconductor island operating as a photo-detector of a third of the photo sensitive layers may be of a third thickness for detecting red light. By way of example, the first thickness may be between about 0.1 um and about 1.5 um; the second thickness may be between about 1.0 um and about 5.0 um; and the third thickness may be between about 2.0 um and about 10.0 um.

The semiconductor layer of at least one of the photo sensitive layers may be formed from a first semiconductor layer bonded to the first surface of the associated glass or glass ceramic substrate via anodic bonding and a second semiconductor layer formed on the first semiconductor layer via epitaxial growth. By way of example, at least one of the first and second semiconductor layers may be formed from a single crystal semiconductor material. Such single crystal semiconductor material may be taken from the group consisting of: silicon (Si), germanium-doped silicon (SiGe), silicon carbide (SiC), germanium (Ge), gallium arsenide (GaAs), GaP, GaN, and InP.

By way of further example, the substrate of at least one of the photo sensitive layers may be a glass substrate and includes: a first layer adjacent to the semiconductor layer with a reduced positive ion concentration having substantially no modifier positive ions; and a second layer adjacent to the first layer with an enhanced positive ion concentration of modifier positive ions, including at least one alkaline earth modifier ion from the first layer. The relative degrees to which the modifier positive ions are absent from the first layer and the modifier positive ions exist in the second layer may be such that substantially no ion re-migration from the glass substrate into the semiconductor layer may occur.

An approach of using stacked layers for different color absorption has been demonstrated in standard CMOS technology by Foveon, Inc. of San Jose, Calif., U.S.A. (see, http://www.foveon.com/article.php?a=67). In such an approach, each pixel unit is provided with three photodiodes that are stacked vertically such that each one occupies different depths in bulk silicon. Thus, each photodiode responds to incident light wavelengths that are absorbed at corresponding silicon depths. The pixel readout electronics is shared among the photodiodes. Since different photodiodes are buried at different silicon depths, their doping profile, dark current, and conversion gain may suffer from non-uniformity which is a major drawback. Another disadvantage of this approach is that response optimization of a single photodiode is difficult to achieve without affecting the other two photodiodes. In SOG stacked imaging applications, however, the photo-detectors for different color channels are physically separated such that their individual optimization is more straightforward. The thickness of different silicon layers and their doping concentrations are easily controlled to allow optimization of the color response in each channel. Thus, better color uniformity and more optimized color response for specific imaging applications may be achieved with the stacked SOG technology. Since each layer in an SOG imager substantially absorbs one of the color channels, no color-filter arrays (CFA) are required. This simplifies sensor fabrication and mitigates CFA alignment problems. It has been shown that the CFA alignment during the fabrication process is becoming a challenge in standard CMOS imagers. In addition, the multilayer SOG approach increases the spatial resolution of the imager by a factor of four with respect to standard CMOS color imagers (which use one of the CFA arrangements, such as a Bayer pattern).

Other aspects, features, advantages, etc. will become apparent to one skilled in the art when the description of the embodiments herein is taken in conjunction with the accompanying drawings.

### BRIEF DESCRIPTION OF THE DRAWINGS

For the purposes of illustrating the various aspects of the embodiments herein, there are shown in the drawings forms that are presently preferred, it being understood, however, that the embodiments described and/or claimed herein are not limited to the precise arrangements and instrumentalities shown.

FIG. 1A is a block diagram illustrating the structure of a CMOS image sensor formed on an SOG substrate in accordance with one or more embodiments herein;

FIG. 1B is a schematic diagram of a circuit suitable for implementing a given pixel structure of the CMOS image sensor of FIG. 1A;

FIG. 1C is a block diagram illustrating the pixel structure of the CMOS image sensor of FIG. 1A;

FIG. 2 is a graph of predicted color response for blue, green and red layers of the CMOS image sensor of FIG. 1A;

FIGS. 3-6 are block diagrams of intermediate structures formed using a fabrication process to achieve a SOG foundation structure suitable for use in constructing the CMOS image sensor of FIG. 1A;

FIG. 7 is block diagram of an intermediate structure achieved using a process for forming a given pixel of a given layer of the CMOS image sensor; and

FIG. 8 is a partial optical graph and partial block diagram illustrating features that may be employed in the CMOS image sensor embodiments herein that provide some correction for optical aberrations.

### DETAILED DESCRIPTION

A CMOS image sensor in accordance with various aspects of the embodiments herein may be implemented in a semiconductor material, such as silicon, using CMOS very-large-scale-integration (VLSI) compatible fabrication processes. One or more embodiments herein contemplate the implementation of a CMOS image sensor on an SOG substrate, such as a silicon-on-glass ceramic (SiOGC) substrate. The SOG substrate is compatible with CMOS fabrication process steps, and permits the photo-detectors and readout transistor circuitry to be implemented in the semiconductor (e.g., silicon) layer. The transparent glass (or glass ceramic) portion of the SOG supports backside illumination and the benefits thereof.

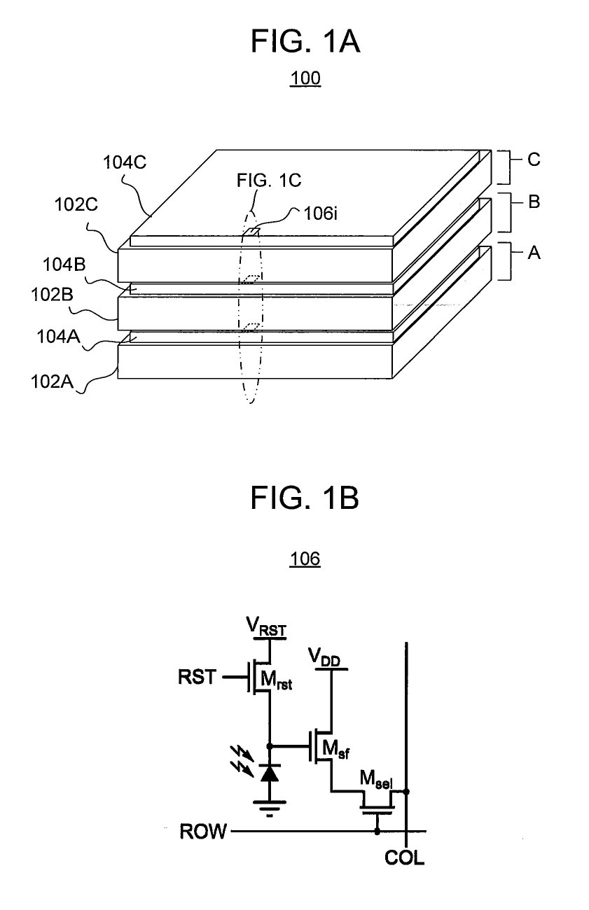

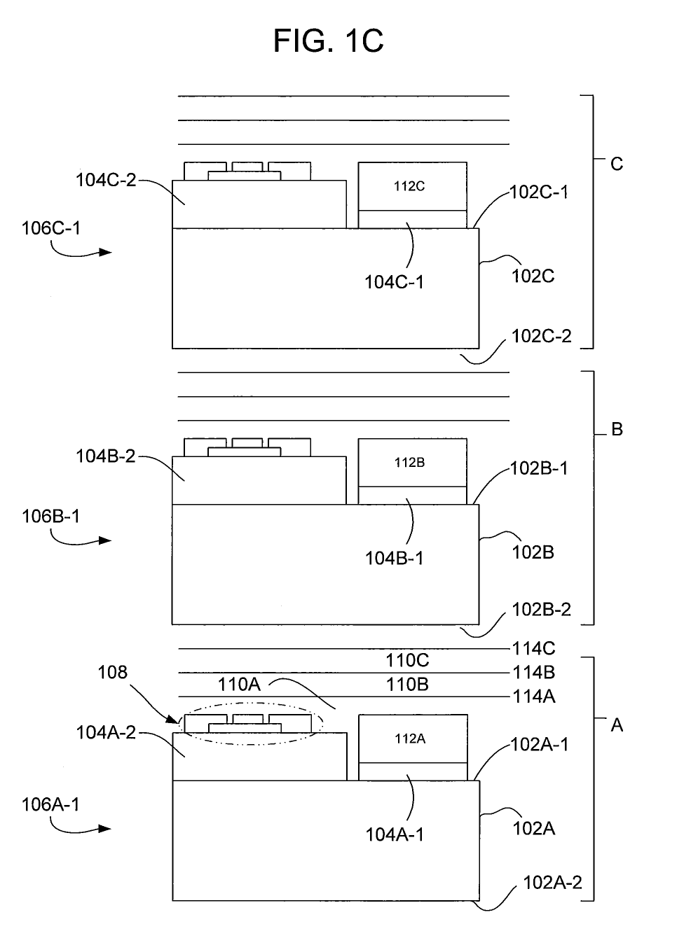

With reference to the drawings, wherein like numerals indicate like elements, there is shown in FIG. 1A a CMOS image sensor 100 formed on a SOG structure in accordance with one or more embodiments herein. The CMOS image sensor 100 includes a stacked configuration, employing a plurality of image sensor layers at level A, level B, and level C. Each image sensor layer may be dedicated to the detection of a particular range of light wavelengths, such as blue, green, and red (or any other desired colors or color combinations, such as blue light, blue and green light, and blue and green and red light). The level A image sensor layer may include a glass or glass ceramic substrate 102A, and a semiconductor layer 104A; the level B image sensor layer may include a glass or glass ceramic substrate 102B, and a semiconductor layer 104B; and finally the level C image sensor layer may include a glass or glass ceramic substrate 102C, and a semiconductor layer 104C. Although three levels are illustrated, any number of layers, e.g., two or more layers may be employed and remain in the scope of the contemplated embodiments. A plurality of CMOS image sensor pixel structures 106i are disposed on and/or within the semiconductor layer 104 of each image sensor layer and collectively form the image sensing function for the CMOS image sensor 100.

By way of example, and not limitation, a circuit diagram of a pixel structure 106 suitable for implementing a given one of the pixel structures 106, of a particular layer, is illustrated in FIG. 1B. The circuitry for implementing a CMOS image sensor pixel may be a so-called 3T cell, including a photo-detector (such as a JFET photogate or pinned photodiode), a transfer gate, a reset gate, and a row select transistor. A first transistor, Mᵣₛₜ, acts as a switch to reset the pixel cell. When the Mᵣₛₜ transistor is turned on, the photodiode is effectively connected to the power supply, V_{RST}, clearing all integrated charge. The second transistor, M_{sf}, acts as a buffer, specifically, a source follower amplifier, which allows the pixel voltage to be measured without removing any accumulated charge. The power supply, V_{DD}, of the M_{sf} transistor may be tied to the power supply of the Mᵣₛₜ transistor. The third transistor, Mₛₑₗ, is the row-select transistor, which operates as a switch that allows a single row of the pixel array to be read by read-out electronics (not shown). It is understood that alternative pixel circuit implementations are permitted without departing from the scope of the embodiments described and/or claimed herein.

With reference to FIGS. 1A and 1C, a cross-section of a given set of pixel structures 106i is illustrated in detail. The set includes, for example, three stacked pixel structures 106A-1, 106B-1, 106C-1 such that each layer includes a pixel structure capable of sensing light at a particular frequency of light (or range of frequencies). The first pixel structure 106A-1 is a first pixel of an array of pixels at level A. A second pixel structure 106B-1 is a first pixel of an array of pixels at level B. And a third pixel structure 106C-1 is a first pixel of an array of pixels at level C. Each pixel structure 106 includes a portion of the glass or glass ceramic substrate 102 at the given level. For example, at level A the glass or glass ceramic substrate 102A includes first and second spaced-apart surfaces 102A-1, 102A-2. A section of the associated semiconductor layer 104A is disposed on the first surface 102A-1 of the glass or glass ceramic substrate 102A. The section of the semiconductor layer 104A includes at least first and second semiconductor islands 104A-1 and 104A-2. The semiconductor island 104A-1 functions as a photo-detector and is sensitive to a respective light wavelength or range of light wavelengths. The semiconductor island 104A-2 includes at least one transistor 108 operating to at least one of: buffer, select, and reset the photo-detector of the semiconductor island 104A-1. In other words, the at least one transistor 108 operates to carry out one or more of the functions of a particular circuit implementation of the pixel structure 106A-1, such as that discussed above with respect to FIG. 1B.

As mentioned above, each level of the CMOS image sensor 100 includes the above-described pixel structure, such as the pixel structures 106B-1 and 106C-1. In this way, a plurality of image sensors (such as three) is disposed one behind the other, which achieves color separation without the use of a color-filter-array (CFA) and also reduces chromatic aberrations. Since the multilayer approach does not require CFA, it is anticipated that the optical cross-talk between pixels will be reduced. In addition to reducing the optical cross-talk, the multilayer approach may reduce the electrical cross-talk between the plurality of color detection layers.

The first imager layer A, which may be closest to the source of light to be detected, is sensitive to relatively short visible wavelengths (e.g., corresponding to the blue light wavelength or wavelengths). Thus, layer A operates to gather most of the blue light component, possibly a small portion of a next higher color component, such as the green light wavelength or range of wavelengths, and almost none of a further color component (e.g., the red light wavelength or wavelengths). The next imager layer B is sensitive to relatively longer visible wavelengths (e.g., corresponding to the green light wavelength or wavelengths). Thus, layer B operates to gather most of the green light component, and possibly a small portion of the next higher color component (e.g., the red light wavelength or wavelengths). Finally, the next imager layer C is sensitive to still longer visible wavelengths (e.g., corresponding to the red light wavelength or wavelengths). Thus, the layer C operates to absorb only the remaining red light component. Further color post-processing circuitry, not shown, may be used to separate the detected mixed color components (or channels) into a standard RGB (or YcrCb) image representation.

Turning back to a particular one of the pixel structures, such as structure 106A-1, the first and second semiconductor islands 104A-1, 104A-2 are isolated from one another via physical trenches which may include a dielectric material, such as silica, disposed therein. The same physical isolation characteristics may also be carried through to the other layers to achieve optical and/or electrical separation of the respective first and second semiconductor islands, for example, first and second semiconductor islands 104B-1 and 104B-2 of level B, and/or first and second semiconductor islands 104C-1 and 104C-2 of level C.

The particular thickness of the first semiconductor island 104A-1 of level A may be established to create color sensitivity at a particular wavelength or range of wavelengths to accommodate an adequate color response of the desired photo-detection function. The first semiconductor island 104A-1 may be of a first thickness, between about 0.1 um and about 1.5 um, for detecting blue light. The first semiconductor island 104B-1 of the second layer B may be of a second thickness, between about 1.0 um and about 5.0 um, for detecting green light. The first semiconductor island 104C-1 of the third layer C may be of a third thickness, between about 2.0 um and about 10.0 um, for detecting red light. These thicknesses assume that the light is absorbed by somewhere between about 10% on the low side and 90% on the high side in one pass of the light into the respective semiconductor islands.

With the above configuration, light is received into the CMOS image sensor 100 through the second surface 102A-2 of the glass or glass ceramic substrate 102A of level A. Assuming that the light is of relatively short wavelength(s) (e.g., corresponding to a blue light component), then such light enters into the respective first semiconductor island 104A-1 (the photo-detector) and is absorbed and sensed. Assuming that the light is of relatively longer wavelength(s) (e.g., corresponding to a green light component), then such light is received into the CMOS image sensor 100 through the second surface 102A-2 of the glass or glass ceramic substrate 102A of level A, passes through the first semiconductor island 104A-1 of level A (possibly being partially absorbed and sensed therein), passes through the second surface 102B-2 of the glass or glass ceramic substrate 102B of level B, and enters into the respective first semiconductor island 104B-1 (the photo-detector) of level B and is absorbed and sensed. Finally, if the light is of still longer wavelength(s) (e.g., corresponding to a red light component), then such light is received into the CMOS image sensor 100 through the second surface 102A-2 of the glass or glass ceramic substrate 102A of level A, passes through the first semiconductor island 104A-1 of level A, passes through the second surface 102B-2 of the glass or glass ceramic substrate 102B of level B, passes through the respective first semiconductor island 104B-1 of level B (possibly being partially absorbed and sensed therein), passes through the second surface 102C-2 of the glass or glass ceramic substrate 102C of level C, and enters into the respective first semiconductor island 104C-1 (the photo-detector) of level C and is absorbed and sensed.

Electrical connections to the respective photo-detectors 104A-1, 104B-1, 104C-1 is achieved by respective contact metallization 112A, 112B, 112C disposed thereon. Electrical connections to the respective contact metallization 112 and the transistors 108 are achieved via one or more layers of interconnection metallization 114A, 114B, 114C, (labeled at level A only for simplicity) including further dielectric material layers 110A, 110B, 110C therebetween.

Among the advantages of the semiconductor on glass or glass ceramic image sensor 100 is the ability to employ back illumination of the photo-sensitive region to increase the fill factor and optical efficiency. Conventional CMOS image sensors fabricated in bulk silicon typically employ about 30% to 40% of the pixel area for gathering light with the remainder taken up in roughly equal proportions by the readout transistors and the wiring layers. Furthermore, as pixel sizes decrease, the stacked wiring layers “shadow” the light sensitive region to reduce the solid angle from which light may reach the photo-detector, which affects optical efficiency. The back illumination characteristic enables an improvement of both the effective fill factor and the optical efficiency. Although the active devices 108 consume some of the pixel area, the wiring layers 114 may pass on top of the photosensitive region without penalty regaining some 30%-40% of the usable area. Therefore, it should be possible to reach fill factors of 60%-70% and optical efficiencies near 100%, i.e., 2π solid angle light acceptance.

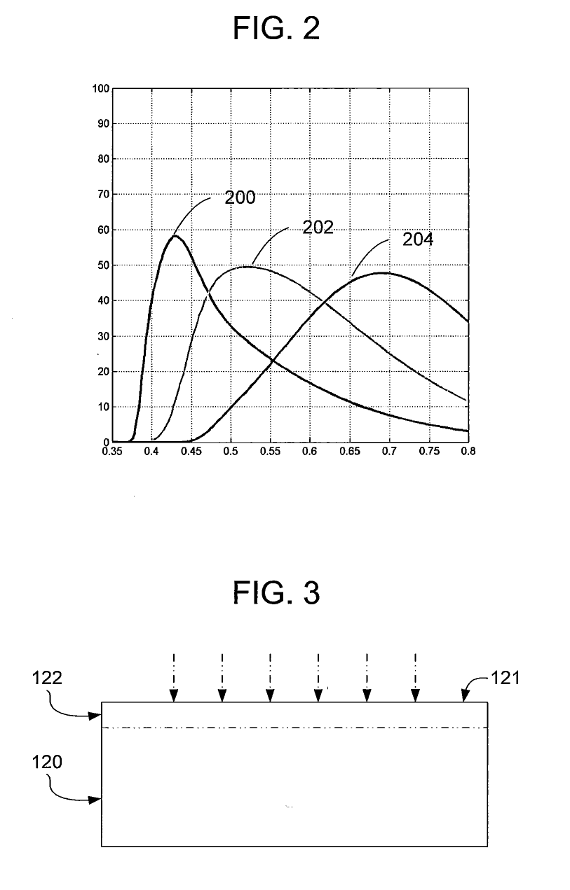

Reference is now made to FIG. 2, which is a graph of predicted color response for blue, green and red layers of the CMOS image sensor 100 of FIG. 1A, assuming that the respective thicknesses of the semiconductor islands 104A-1, 104B-1, and 104C-1 are 0.5 um, 2 um, and 8 um. The ordinate axis of the illustrated graph is the percentage of color response (e.g., the sensitivity to a particular wavelength of light) and the abscissa is wavelength in um. The predicted responses of the blue (200), green (202) and red (204) layers are reasonable, useful, and commercially viable for a CMOS image sensor.

In addition to adjusting the layer thickness for improved (or potentially optimal) quantum efficiency in each color channel, the stacked CMOS image sensor 100 permits each color layer A, B, C to be adjusted in terms of spatial resolution (i.e., the pixel density—the number pixel units/area) for a specific imaging application. For example, each level may include higher or lower pixel density than adjacent levels. By way of example, the first level A for blue component sensitivity may be designed with less spatial resolution (e.g., about four times less) than the second level B for green component sensitivity. Similarly, the third level C for red component sensitivity may be designed with less spatial resolution (e.g., about four times less) than the second level B. This freedom of design simplifies the design and reduces the overall cost of the CMOS imager without significantly degrading image quality.

In one or more embodiments, the substrate 102 of one or more of the layers A, B, C may be a glass ceramic substrate. The glass ceramic substrate 102 may be alkali-free, and expansion-matched to the semiconductor layer 104. The glass-ceramic substrate 102 possess excellent thermal stability, and maintains transparency and dimensional stability for many hours at temperatures in excess of 900° C., which is desirable for relatively high temperature CMOS processes. The material also provides excellent chemical durability to the etchants used in the CMOS fabrication process. Additionally, any metal ions in the glass ceramic substrate 102 pose a negligible contamination threat during the CMOS fabrication process at elevated temperatures. Modifier ions are also trapped in the glass ceramic substrate 102 and cannot migrate into the semiconductor layer 104, which might otherwise degrade the electrical and/or optical characteristics of the pixel structures 106.

It is noted that lower temperature CMOS processes are available, which may be used when certain glass substrates 102 are employed that are less stable at higher CMOS processing temperatures, such as 900° C. or greater. Such glasses include EAGLE XG™ and JADE™ available from Corning Incorporated, Corning, N.Y., each of which have strain points of less than about 700° C. The lower temperature CMOS processes, however, usually result in lower electrical and/or optical performance.

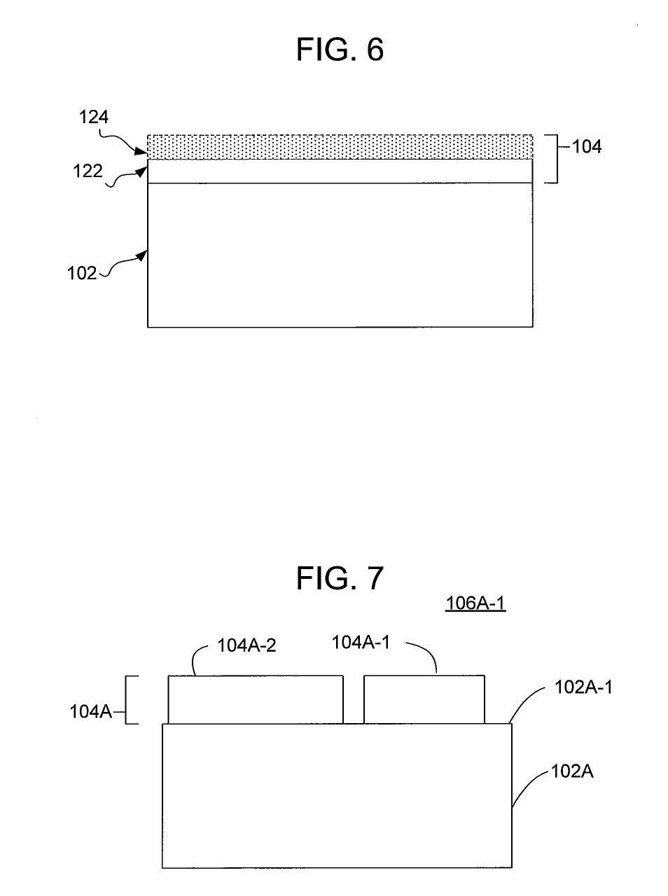

Reference is now made to FIGS. 3-7, which illustrate processes and structures useful in implementing one or more embodiments of the CMOS image sensor 100. FIGS. 3-6 are block diagrams of intermediate structures formed using a fabrication process to achieve a SOG foundation structure suitable for use in constructing one layer (e.g., layer A) of the CMOS image sensor 100. The foundation structure is shown in FIG. 6 and includes the glass or glass ceramic substrate 102 and the semiconductor layer 104 bonded thereto.

The semiconductor layer 104 may be bonded to the glass substrate 102 using any of the existing techniques known to those of skill in the art. Among the suitable techniques is bonding using an electrolysis process. A suitable electrolysis bonding process is described in U.S. Pat. No. 7,176,528, the entire disclosure of which is hereby incorporated by reference. Portions of this process are discussed below.

With reference to FIG. 3, a semiconductor donor wafer 120 is subject to ion implantation, such as hydrogen and/or helium ion implantation, to create a zone of weakness below a bonding surface 121 of the semiconductor donor wafer 120.

The semiconductor material of the semiconductor donor wafer 120 (and thus the semiconductor layer 104) may be in the form of a substantially single-crystal material. The term “substantially” is used to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor material of the semiconductor donor wafer 120 (and thus the semiconductor layer 104) is formed from silicon. It is understood, however, that the semiconductor material may be a silicon-based semiconductor or any other type of semiconductor, such as, the III-V, II-IV-V, etc. classes of semiconductors. Examples of these materials include: silicon (Si), germanium-doped silicon (SiGe), silicon carbide (SiC), germanium (Ge), gallium arsenide (GaAs), GaP, GaN, and InP.

The substrate 102 may be formed from an oxide glass or an oxide glass-ceramic. By way of example, the glass substrate 102 may be formed from glass substrates containing alkaline-earth ions and may be silica-based, such as, substrates made of CORNING INCORPORATED GLASS COMPOSITION NO. 1737 or CORNING INCORPORATED GLASS COMPOSITION NO. EAGLE 2000®. The glass or glass-ceramic substrate 102 may be designed to match a coefficient of thermal expansion (CTE) of one or more semiconductor materials (e.g., silicon, germanium, etc.) of the layer 104 that are bonded together. The CTE match ensures desirable mechanical properties during heating cycles of the deposition process.

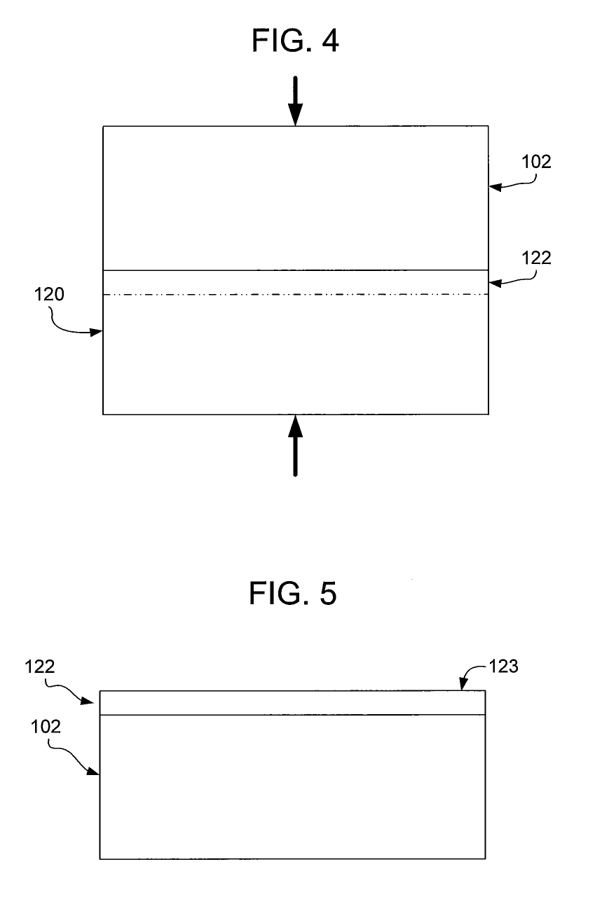

With reference to FIG. 3-4, the glass or glass ceramic substrate 102 and the bonding surface 121 (FIG. 3) of the donor semiconductor wafer 120 are brought into direct or indirect contact and are heated under a differential temperature gradient. Mechanical pressure is applied to the intermediate assembly (e.g., about 1 to about 50 psi.) and the structure is taken to a temperature within about +/−150 degrees C. of the strain point of the glass or glass ceramic substrate 102. A voltage is applied with the donor semiconductor wafer 120 at a positive potential and the glass or glass ceramic substrate 102 a negative potential. The intermediate assembly is held under the above conditions for some time (e.g., approximately 1 hour or less), the voltage is removed, and the intermediate assembly is allowed to cool to room temperature.

With reference to FIG. 5, at some point during the above process, the donor semiconductor wafer 120 and the glass or glass ceramic substrate 102 are separated, to obtain a glass or glass ceramic substrate 102 with a relatively thin exfoliation layer 122 of the semiconductor material bonded thereto. The separation of the donor semiconductor wafer 120 from the exfoliation layer 122 that is bonded to the glass or glass ceramic substrate 102 is accomplished through application of stress to the zone of weakness within the donor semiconductor wafer 120, such as by a heating and/or cooling process. It is noted that the characteristics of the heating and/or cooling process may be established as a function of a strain point of the glass or glass ceramic substrate 102. Although the embodiments described and/or claimed herein are not limited by any particular theory of operation, it is believed that glass or glass ceramic substrates 102 with relatively low strain points may facilitate separation when the respective temperatures of the donor semiconductor wafer 120 and the glass or glass ceramic substrate 102 are falling or have fallen during cooling. Similarly, it is believed that glass or glass ceramic substrates 102 with relatively high strain points may facilitate separation when the respective temperatures of the donor semiconductor wafer 120 and the glass or glass ceramic substrate 102 are rising or have risen during heating. Separation of the donor semiconductor wafer 120 and the glass or glass ceramic substrate 102 may also occur when the respective temperatures thereof are neither substantially rising nor falling (e.g., at some steady state or dwell situation).

In the case of glass substrates 102, the application of the electrolysis bonding process causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the semiconductor/glass interface, forming: (1) a reduced positive ion concentration layer in the glass substrate 102 adjacent the semiconductor/glass interface; and (2) an enhanced positive ion concentration layer of the glass substrate 102 adjacent the reduced positive ion concentration layer. This accomplishes a number of features: (i) an alkali or alkaline earth ion free interface (or layer) is created in the glass substrate 102; (ii) an alkali or alkaline earth ion enhanced interface (or layer) is created in the glass substrate 102; (iii) an oxide layer is created between the exfoliation layer 122 and the glass substrate 102; and (iv) the glass substrate 102 becomes very reactive and bonds to the exfoliation layer 122 strongly with the application of heat at relatively low temperatures. Additionally, relative degrees to which the modifier positive ions are absent from the reduced positive ion concentration layer in the glass substrate 102, and the modifier positive ions exist in the enhanced positive ion concentration layer are such that substantially no ion re-migration from the glass substrate 102 into the exfoliation layer 122 (and thus into any of the structures later formed thereon or therein).

An alternative embodiment may include further processing steps to transform a glass substrate into a glass-ceramic substrate 102. In this regard, the structure of FIG. 5 is treated as an intermediate structure in which the glass substrate 102 is a (precursor) glass substrate 102. The precursor glass substrate 102 is cerammed via a heat treatment step in an inert atmosphere such as argon. The ceramming or heat-treatment step generally follows a heat treatment cycle where the intermediate structure is held at a certain temperature to nucleate the crystals of the precursor glass substrate 102 followed by a higher temperature hold for crystal growth. In an alternative embodiment, a heat treatment that does not involve nucleation hold temperature may be utilized. In such an embodiment the ramp up schedule to the crystal growth hold temperature is sufficiently slow to achieve the necessary nucleation of the crystals, for example, a rate no greater than about 50° C./hr.

As a result of the above-described heat-treatment, a portion of the precursor glass substrate 102 remains glass and a portion is converted to a glass-ceramic structure. Specifically, the portion which remains an oxide glass is that portion of the precursor glass substrate 102 closest to the semiconductor exfoliation layer 122, the aforementioned reduced positive ion concentration layer. This is due to the fact that there is a lack of spinel forming cations Zn, Mg in this portion of the precursor glass substrate 102 (because the positive modifier ions moved away from the interface during the bonding process). At some depth into the precursor glass substrate 102 (specifically that portion of the precursor glass substrate 102 with an enhanced positive ion concentration) there are sufficient ions to enable crystallization and to form a glass-ceramic layer with an enhanced positive ion concentration.

It follows that the remaining precursor glass portion 102 (a bulk glass portion at still further depths into the substrate 102 away from the interface) also possesses sufficient spinel forming cations to achieve crystallization. The resultant glass-ceramic substrate structure is thus a two layer glass-ceramic portion comprised of a layer having an enhanced positive ion concentration, which is adjacent the remaining oxide glass layer, and a bulk glass-ceramic layer.

Irrespective of whether one employs a glass substrate 102 or a cerammed substrate, the cleaved surface 123 of the SOI structure just after exfoliation may exhibit excessive surface roughness, implantation damage, etc. Post processing may be carried out to correct the roughness, implantation damage, etc.

With reference to FIG. 6, it is possible that the thickness of the exfoliation layer 122 may be on the order of less than about 1 um. As the thicknesses of one or more of the semiconductor islands 104A-1, 104B-1 and 104C-1 (FIG. 1C) may need to be greater than 1 um for efficient light absorption, the process may include forming the final semiconductor layer 104 by thickening the exfoliated semiconductor layer 122 to a thickness greater than 1 um. This may be carried out by disposing a further semiconductor layer 124 on the exfoliated semiconductor layer 122 via epitaxial growth. Any of the known or hereinafter developed processes for epitaxial growth on an existing semiconductor layer may be employed. The resultant final semiconductor layer 104 is thus a first semiconductor layer 122 bonded to the first surface 102A of the glass or glass ceramic substrate 102 via anodic bonding and a second semiconductor layer 124 formed on the first semiconductor layer 122 via epitaxial growth.

FIG. 7 is a block diagram of an intermediate structure achieved using a process for forming each pixel 106i (FIG. 1A) of a given layer of the CMOS image sensor 100. Each pixel structure, such as the illustrated pixel 106A-1 of layer A, is formed by isolating the first and second semiconductor islands 104A-1 and 104A-2 using vertical preferential etching. The specific process steps in achieving island isolation in semiconductor materials are well known in the art and may applied here to achieve deep trench isolation in the semiconductor layer 104, such as vertical preferential etching extending to about 7 um deep or more.

If necessary, a process of thinning at least one of the first and second semiconductor islands 104A-1, 104A-2 is performed such that the thickness for photo-detection of the desired color wavelength(s) is achieved. A known or hereinafter developed semiconductor etch process may be used to achieve the desired thickness of each island. As discussed above, the thickness of the first semiconductor island 104A-1 of the first layer A may be of a thickness of between about 0.1 um and about 1.5 um, for detecting blue light. The first semiconductor island 104B-1 of the second layer B may be of a thickness between about 1.0 um and about 5.0 um, for detecting green light. And the first semiconductor island 104C-1 of the third layer C may be of a thickness between about 2.0 um and about 10.0 um, for detecting red light.

Known processes may be carried out to form the at least one transistor 108 (such as a thin-film-transistor, TFT) on the second semiconductor island 104 of each layer in order to obtain the proper circuitry for buffering, selecting, and resetting the photo-detectors. Turning again to FIG. 1 C, the dielectric material, such as silica, may then be applied to electrically isolate the semiconductor islands 104 and prevent electrical cross-talk between the photo-detectors of adjacent pixels on the same level and of differing levels. Further dielectric layers 110B, 110C and metallization layers 114A, 114B, 114C are deposited using known semiconductor fabrication techniques to achieve the final structure of a given layer. These fabrication techniques may include subjecting the semiconductor layer 104 to patterned oxide and metal deposition procedures (e.g., etching techniques) and doping using ion shower techniques (and or any of the other known techniques). Inter-layers, contact holes, and metal contacts may be disposed using known fabrication techniques to produce the given layer.

When the fabrication of the respective layers A, B, C, etc. are completed, they may be stacked together using layer-to-layer alignment followed by thermal bonding techniques that are well established, for example from micro electro mechanical system (MEMS) manufacturing. Alignment of the layers A, B, C, relative to one another should be performed to within at least about 1 micron accuracy, and the thermal bonding should be performed at temperatures less than about 400° C. This aligned layer bonding approach allows for a three dimensional interconnection of the layers A, B, C.

In accordance with one or more further embodiments, the stacked CMOS imager 100 may include features that compensate for one or more types of chromatic aberrations. There are two types of chromatic aberrations: lateral and longitudinal. The longitudinal type of chromatic aberration is associated with the response of an optical system to light that is incident at a right angle with respect to an imaging plane. More specifically, different wavelengths in optical systems that are prone to longitudinal aberrations will have different focal lengths. In other words, different focal lengths result at different color wavelengths. Thus, even if, for example, the focal point of green wavelengths fall on the imaging plane, the focal points of the blue, red or other wavelengths may not fall on the imaging plane. The existence of longitudinal aberrations degrades the optical detection characteristics of the system.

The lateral type of chromatic aberration is associated with the response of the optical system to light that is incident at an oblique angle with respect to the imaging plane. More specifically, different color wavelengths in an optical system prone to lateral aberrations will focus at different lengths from the optical axes. Again, by way of example, even if the focal point of green wavelengths fall on the proper pixel (or pixels) of the imaging plane, the focal points of the blue, red or other wavelengths may not fall on the same pixel or pixels of the imaging plane. Indeed, they may be laterally offset in any number of directions.

Conventional mechanisms for compensating for chromatic aberrations in CMOS and CCD image sensors employ relatively expensive optical systems. In many low-end commercial imaging applications, a compound lens system (e.g., an achromatic lens doublet), which requires precise alignment, is used to reduce the chromatic aberrations. A compound lens system usually requires two or more optical elements with different refractive indexes. However, not even these complex lens systems are completely resilient to chromatic aberrations, especially at full wide angles.

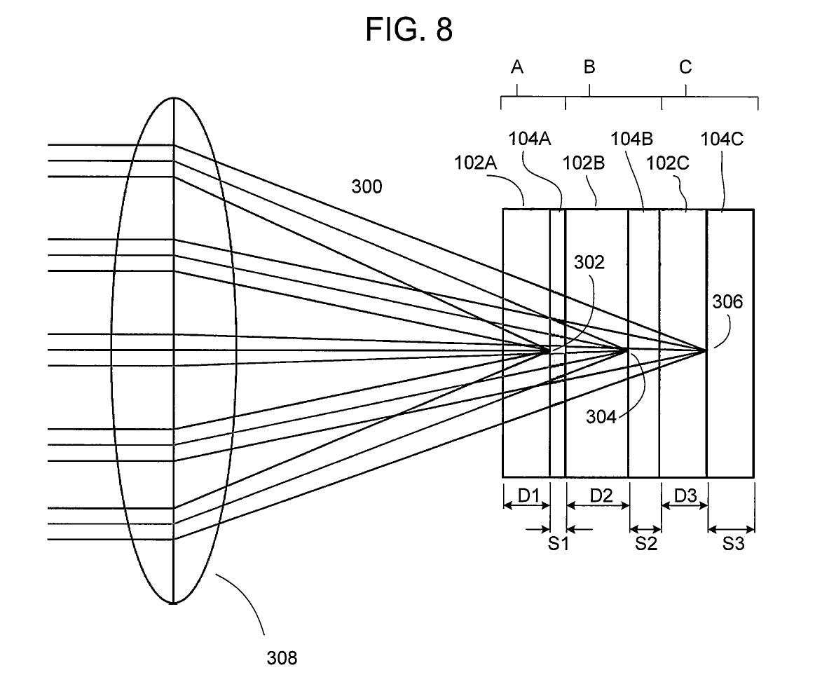

Reference is now made to FIG. 8, which illustrates certain features in accordance with one or more embodiments, which address the chromatic aberration problems. The CMOS imaging system may include a plurality of layers A, B, C, in which the respective thicknesses of at least two of the glass or glass ceramic substrates differ in order to provide focal length corrections. In particular, the respective thicknesses D1, D2, D3 associated with the different color planes at level A, B, C, may be adjusted so that each color wavelength or wavelengths are properly focused. Focal points of each color of incident light 300 may be adjusted to fall on the correct color plane (e.g., at points 302 for blue, 304 for green, and 306 for red).

By way of example, a 7.53 mm effective focal length single element lens may be made from SF57 Schott glass, which operates as a landscape lens with external aperture stop. In such an example, the thickness range for Dl may be no glass up to 1 mm, the thickness for D2 may be 0.180 mm, and the thickness for D3 may be 0.100 mm. Such thicknesses may correct for longitudinal or axial chromatic aberrations, assuming that the sensor substrate material is Corning EAGLE XG glass (with nd=1.51, and V=61.6). An optional, and relatively simple, refractive element 308 may be employed to assist in the focusing characteristics of the system.

In some applications, such as a quarter-inch optical format, the differences in focal lengths of each color may be on the order of only hundreds of micrometers, which is relatively small compared to desirable thicknesses for the glass or glass ceramic substrates 102. In order to increase the extent of the longitudinal aberrations to accommodate thicker glass or glass ceramic substrates 102, a holographic optical element (HOE) with large positive dispersion may be used. In such an embodiment, the basic structure illustrated and discussed in FIG. 8 may be employed (with or without the refractive element 308) in combination with the HOE using known interconnection techniques. It has been demonstrated through experimentation that a relatively inexpensive HOE may be used to extend the aberrations such that the focal points of the blue and red components are separated by as much as 3.6 mm, which should be sufficient to accommodate thicker glass or glass ceramic substrates 102 of about 1 mm or so. In order to reduce the so-called coma aberrations commonly seen in HOE applications, an aperture stop shifted in front of the HOE may be used.

One of the characteristics seen in employing an HOE is reduced field flatness at the focal plane (i.e., increased field curvature). It has been demonstrated that using an HOE with larger positive dispersion in order to accommodate thicker glass or glass ceramic substrates 102 will result in more deteriorated field flatness at the focal plane (at the photo detector). Therefore, there is a trade-off between the thickness of the glass or glass ceramic substrate 102 and the extent of the field curvature. It is anticipated that as SOG technology improves, allowing thinner glass substrates to be implemented (e.g., down to about 50 um), an HOE with smaller dispersion coefficients may be utilized while maintaining better field flatness.

Also illustrated in FIG. 8, the thicknesses of two or more of the semiconductor layers 104A, 104B, 104C (S1 for blue, S2 for red, and S3 for green) may be adjusted for improved (or optimal) color separation and response.

Additionally, lateral chromatic aberration can be corrected by shifting the location of the pixels of a given sensor layer relative to sensor elements in the other sensor layers. The specific amount of shift depends on the angle that the chief ray (the central ray in an off-axis imaging bundle) makes with the sensor. By way of example, a system operating at an input field angle of 23.5° and a chief ray angle of 20.2° incident on the sensor substrate can have a lateral pixel offset of the red sensor layer relative to the green layer in excess of +28.7 μm. The positive number indicates that a red pixel is shifted away from the optical axis relative to the green pixel at this same object field height. The lateral pixel offset of the blue sensor layer relative to the green layer can be in excess of −82.2 μm; the blue pixel is shifted toward the optical axis relative to the green pixel at this same object field height. The offsets just described in the above example would be the offsets at the edge of the field of view. The pixel offsets would vary linearly from the center of the sensor to edge with radial symmetry. Thus, there would be no offset at the center of the sensor and the offset increases linearly until reaching the field radius described above. For the lens described in this example, the radius would be approximately 2.1175 mm for the green sensor layer. If the sensor has a square for rectangular geometry, some sensor elements would lay outside the inscribed circle just described. Sensors that lay outside this circle would have offsets that are linearly larger than listed above. Note, that shifting the location of the aperture stop changes the lateral chromatic aberration and also the angle of the chief ray. For a given sensor geometry, the lateral chromatic aberration and chief ray angle of the image bundle can be optimized to match the sensor. Therefore, a sensor could be optimized for a given lens lateral chromatic aberration and chief ray angle or a lens could be optimized for a given sensor configuration.

In summary, the embodiments described and/or claimed herein may be directed to CMOS image sensor applications. Among the advantages of at least some of the embodiments described and/or claimed herein include:
Permitting processing steps at temperatures exceeding 900° C., which is compatible with CMOS fabrication processes for implementing an image sensor chip.
Reducing or eliminating the need for external color filter array optics, as color separation may be achieved via a stacked configuration with the semiconductor thickness of each layer modified for improved sensitivity.
Reducing or eliminating the need for complicated waveguide/light-pipe structures to efficiently couple light to the photo-detectors due to the use of backside illumination, through the second surface of the glass or glass ceramic substrate. The backside illumination may also relax strict requirements to have low metallization stack-up height.
Reducing or eliminating intra- and/or inter-pixel cross-talk through the use of the isolated photo-detector islands and the insulating glass or glass ceramic substrate.
Permitting the use of relatively thinner substrates over competing technologies, which reduces the pixel electrical crosstalk and thereby improves the image sensor MTF characteristics.
Permitting adjustment in the thickness of the absorption space in the semiconductor on glass or glass ceramic substrate with relative ease to meet the trade-off associated with the red channel absorption efficiency versus the electrical crosstalk.
Increasing photo-detection efficiency and/or reducing the thickness of the photo-detector islands through the use of the retro-reflector (such as an appropriate contact metal).
Permitting adjustment of the glass or glass ceramic substrate thicknesses (associated with the different color planes) so that each wavelength is properly focused, which significantly relaxes the optical system requirement in regards to chromatic aberrations.

Although the embodiments herein have been described with reference to particular details, it is to be understood that these embodiments are merely illustrative. It is therefore to be understood that numerous modifications may be made to the illustrative embodiments and that other arrangements may be devised without departing from the spirit and scope of the appended claims.

1. A CMOS image sensor, comprising:
a plurality of photo sensitive layers, each layer including:
a glass or glass ceramic substrate having first and second spaced-apart surfaces;
a semiconductor layer disposed on the first surface of the glass or glass ceramic substrate; and
a plurality of pixel structures formed in the semiconductor layer, each pixel structure including a plurality of semiconductor islands, at least one island operating as a color sensitive photo-detector sensitive to a respective range of light wavelengths,
wherein the plurality of photo sensitive layers are stacked one on the other, such that incident light enters the CMOS image sensor through the first spaced-apart surface of the glass or glass ceramic substrate of one of the plurality of photo sensitive layers, and subsequently passes into further photo sensitive layers if one or more wavelengths of the incident light are sufficiently long.

2. The CMOS image sensor of claim 1, wherein the thicknesses of at least two semiconductor islands of respective color sensitive photo-detectors on differing photo sensitive layers differ as a function of the respective range of light wavelengths to which they are sensitive.

3. The CMOS image sensor of claim 2, wherein at least one of:
a first semiconductor island operating as a photo-detector of a first of the photo sensitive layers is of a first thickness for detecting blue light;
a second semiconductor island operating as a photo-detector of a second of the photo sensitive layers is of a second thickness for detecting green light; and
a third semiconductor island operating as a photo-detector of a third of the photo sensitive layers is of a third thickness for detecting red light.

4. The CMOS image sensor of claim 3, wherein:
the first thickness is between about 0.1 um and about 1.5 um;
the second thickness is between about 1.0 um and about 5.0 um; and
the third thickness is between about 2.0 um and about 10.0 um.

5. The CMOS image sensor of claim 3 wherein:
the glass or glass ceramic substrate of the first photo sensitive layer is of a thickness ranging from about 0 to 1 mm, where about 0 mm is the thickness when the first photo sensitive layer is bonded to the second photo sensitive layer;
the glass or glass ceramic substrate of the second photo sensitive layer has a thickness ranging from about 0.180 mm to 0.5 mm; and
the glass or glass ceramic substrate of the third photo sensitive layer has a thickness ranging from about 0.1 mm to 0.5 mm.

6. The CMOS image sensor of claim 1, wherein the semiconductor layer of at least one of the photo sensitive layers is formed from a first semiconductor layer bonded to the first surface of the associated glass or glass ceramic substrate via anodic bonding and a second semiconductor layer formed on the first semiconductor layer via epitaxial growth.

7. The CMOS image sensor of claim 6, wherein at least one of:
at least one of the first and second semiconductor layers is formed from a single crystal semiconductor material; and
the single crystal semiconductor material is taken from the group consisting of: silicon (Si), germanium-doped silicon (SiGe), silicon carbide (SiC), germanium (Ge), gallium arsenide (GaAs), GaP, GaN, and InP.

8. The CMOS image sensor of claim 1, wherein:
the substrate of at least one of the photo sensitive layers is a glass substrate and includes:
a first layer adjacent to the semiconductor layer with a reduced positive ion concentration having substantially no modifier positive ions; and
a second layer adjacent to the first layer with an enhanced positive ion concentration of modifier positive ions, including at least one alkaline earth modifier ion from the first layer.

9. The CMOS image sensor of claim 8, wherein relative degrees to which the modifier positive ions are absent from the first layer and the modifier positive ions exist in the second layer are such that substantially no ion re-migration from the glass substrate into the semiconductor layer may occur.

10. The CMOS image sensor of claim 1, wherein the substrate is a glass ceramic substrate operating to withstand CMOS processing temperatures of at least 900° C.

11. The CMOS image sensor of claim 1, wherein the glass or glass ceramic substrate includes a glass layer portion located proximate to the first surface, and a two-layer glass-ceramic portion having a first glass ceramic layer with an enhanced positive ion concentration located adjacent to the glass layer portion, and a second glass ceramic layer of bulk glass-ceramic located adjacent to the first glass ceramic layer.

12. A method of forming a CMOS image sensor, comprising:
(a) bonding a semiconductor donor wafer to a first surface of a glass or glass-ceramic substrate using an anodic bonding process;
(b) separating the semiconductor donor wafer from the glass or glass-ceramic substrate leaving an exfoliated semiconductor layer bonded thereto;
(c) forming a plurality of pixel structures, each with at least one color photo-detector including a semiconductor island that is sensitive to light, in the final semiconductor layer to produce a photo-sensitive layer;
(d) forming a plurality of photo-sensitive layers using steps (a) through (c) and stacking them one on the other, such that in operation incident light enters the CMOS image sensor through the first spaced-apart surface of the glass or glass ceramic substrate of one of the plurality of photo sensitive layers, and subsequently passes into further photo sensitive layers if one or more wavelengths of the incident light are sufficiently long.

13. The method of claim 12, wherein the step of (c) forming a plurality of pixel structures in the final semiconductor layer includes: thinning at least one of the final semiconductor layer and the respective semiconductor islands thereof, such that a resulting thickness is a function of a desired sensitivity to a range of light wavelengths.

14. The method of claim 13, wherein respective thicknesses of at least two semiconductor islands of respective color sensitive photo-detectors on differing photo sensitive layers differ as a function of the respective range of light wavelengths to which they are sensitive.

15. The method of claim 14, wherein at least one of:
a first semiconductor island operating as a photo-detector of a first of the photo sensitive layers is of a first thickness for detecting blue light;
a second semiconductor island operating as a photo-detector of a second of the photo sensitive layers is of a second thickness for detecting green light; and
a third semiconductor island operating as a photo-detector of a third of the photo sensitive layers is of a third thickness for detecting red light.

16. The method of claim 15, wherein:
the first thickness is between about 0.1 um and about 1.5 um;
the second thickness is between about 1.0 um and about 5.0 um; and
the third thickness is between about 2.0 um and about 10.0 um.

17. The method of claim 12, wherein at least one of:
prior to the step of (c) forming a plurality of pixel structures, the method further comprises: forming a final semiconductor layer by thickening the exfoliated semiconductor layer to a thickness greater than about 1 um; and
the step of thickening the exfoliated semiconductor layer includes disposing a further semiconductor layer on the exfoliated semiconductor layer via epitaxial growth.

18. The method of claim 12, wherein:
the substrate is a glass substrate;
the bonding process includes applying heat, pressure and voltage to the semiconductor donor wafer and the glass substrate such that:
a first layer of the glass substrate adjacent to the exfoliated semiconductor layer includes a reduced positive ion concentration having substantially no modifier positive ions; and
a second layer of the glass substrate adjacent to the first layer includes an enhanced positive ion concentration of modifier positive ions, including at least one alkaline earth modifier ion from the first layer.

19. The method of claim 18, wherein relative degrees to which the modifier positive ions are absent from the first layer and the modifier positive ions exist in the second layer are such that substantially no ion re-migration from the glass substrate into the final semiconductor layer may occur.

20. The method of claim 12, wherein the substrate is a glass ceramic substrate operating to withstand CMOS processing temperatures of at least 900° C.

21. The method of claim 12, wherein the glass or glass ceramic substrate includes a glass layer portion located proximate to the first surface, and a two-layer glass-ceramic portion having a first glass ceramic layer with an enhanced positive ion concentration located adjacent to the glass layer portion, and a second glass ceramic layer of bulk glass-ceramic located adjacent to the first glass ceramic layer.
